(19) United States
(12) Patent Application Publication
(10) Pub. No.: US 2026/0190549 A1
(43) Pub. Date: Jul. 2, 2026

(54) HIGH-BRIGHTNESS, LOW-LEAKAGE, AND HIGHLY RELIABLE ALGAINP YELLOW-GREEN LED EPITAXIAL WAFER

(71) Applicant: FOCUS LIGHTINGS TECH CO., LTD., SUZHOU (CN)

(72) Inventor: YAO ZHANG, SUZHOU (CN)

(21) Appl. No.: 19/018,186

(22) Filed: Jan. 13, 2025

Related U.S. Application Data
(63) Continuation of application No. PCT/CN2025/070518, filed on Jan. 3, 2025.

(30) Foreign Application Priority Data
Dec. 31, 2024 (CN) 202411977272.7

(51) Int. Cl. H10H 20/824; H10H 20/812; H10H 20/816; H10H 20/832

(52) U.S. Cl. CPC H10H 20/824; H10H 20/812; H10H 20/8162; H10H 20/832

(57) ABSTRACT

This invention discloses a high-brightness, low-leakage, and highly reliable AlGaInP yellow-green LED epitaxial wafer. The epitaxial wafer comprises, in sequence, an N-type gallium arsenide (GaAs) buffer layer, an N-type gallium indium phosphide (GaInP) etch stop layer, an N-type GaAs ohmic contact layer, an N-type aluminum gallium indium phosphide (AlGaInP) current spreading layer, an N-type electron blocking layer, an N-type aluminum indium phosphide (AlInP) confinement layer, a multiple quantum well (MQW) layer, a P-type AlInP confinement layer, a P-type gallium phosphide (GaP) current spreading layer, and a P-type GaP ohmic contact layer grown sequentially on a GaAs substrate. By introducing an electron blocking layer, a graded quantum barrier thickness design, and a magnesium diffusion barrier layer, the invention effectively suppresses electron leakage and magnesium diffusion, reduces non-radiative recombination, and significantly improves the luminous efficiency and high-temperature operational stability of the LED.

### CROSS-REFERENCE TO RELATED APPLICATION

This application is a continuation of International Application No. PCT/CN2025/070518, filed on Jan. 3, 2025, the disclosure of which is hereby incorporated by reference in its entirety.

### TECHNICAL FIELD

The present invention relates to the technical field of light-emitting diodes (LED), specifically to a high-brightness, low-leakage, and highly reliable aluminum gallium indium phosphide (AlGaInP) yellow-green LED epitaxial wafer.

### BACKGROUND

AlGaInP yellow-green LED chips provide efficient, energy-saving, and environmentally friendly lighting solutions in household lighting, commercial lighting, and public illumination. In addition, they can be used to manufacture high-resolution and high-color-fidelity displays, enhancing the realism and delicacy of visual experiences. Meanwhile, yellow-green LED chips have high-speed and high-efficiency data transmission capabilities, playing a significant role in advancing modem optical communication networks.

The conventional quaternary AlGaInP short-wavelength LED epitaxial structure typically includes: a gallium arsenide (GaAs) substrate, followed sequentially by an N-type gallium arsenide (GaAs) buffer layer, an N-type gallium indium phosphide (GaInP) etch stop layer, an N-type gallium arsenide (GaAs) ohmic contact layer, an N-type aluminum gallium indium phosphide (AlGaInP) current spreading layer, an N-type aluminum indium phosphide (AlInP) confinement layer, a multiple quantum well (MQW) layer, a P-type aluminum indium phosphide (AlInP) confinement layer, a P-type gallium phosphide (GaP) current spreading layer, and a P-type gallium phosphide (GaP) ohmic contact layer.

This structure demonstrates good luminous efficiency and high reliability in practical applications. However, as the material system advances toward shorter wavelengths, it encounters many challenges, particularly regarding the significant impact of aluminum content variations on device performance.

With the increase in aluminum content in the multiple quantum well (MQW) layer, the AlGaInP material gradually transitions from a direct bandgap to an indirect bandgap, requiring phonon participation during the light-emission process. This transition significantly reduces the quantum efficiency of recombination luminescence, and the probability of electron-hole recombination decreases accordingly.

Additionally, since the electron mobility is much higher than hole mobility, under non-equilibrium conditions, a large number of electrons easily leak into the P-type semiconductor region, increasing non-radiative recombination. This electron leakage not only leads to a reduction in luminous efficiency but also causes localized heat accumulation in the interface layer region, narrowing the semiconductor bandgap and further exacerbating electron leakage issues.

On the other hand, under high-temperature operating conditions, the magnesium (Mg) element in P-type doping easily diffuses into the quantum well region, forming impurity energy levels that trap electrons, further increasing non-radiative recombination, and causing the quantum well luminous efficiency to continuously decline.

Furthermore, as the device operating time increases, this effect gradually accumulates, resulting in a continuous decrease in device brightness and a significant reduction in reliability.

This coupled interaction between electron leakage and magnesium diffusion forms a vicious cycle, severely restricting the performance improvement and stability of short-wavelength AlGaInP LED devices.

### SUMMARY

To address the above problems, the present invention provides an improved short-wavelength high-brightness yellow-green AlGaInP epitaxial wafer.

The specific technical solution of the present invention is as follows:

A high-brightness, low-leakage, and highly reliable AlGaInP yellow-green LED epitaxial wafer, characterized by comprising the following layers sequentially grown on a gallium arsenide (GaAs) substrate:
An N-type GaAs buffer layer, with a thickness of 150-200 nm, a Si doping concentration of 1×10¹⁸-2×10¹⁸ atoms/cm³, and the dopant being Disilane (Si₂H₆);
An N-type GaInP etch stop layer, with a thickness of 100-200 nm, a Si doping concentration of 1×10¹⁸-3×10¹⁸ atoms/cm³, and the dopant being Disilane (Si₂H₆);
An N-type GaAs ohmic contact layer, with a thickness of 30-100 nm, a carrier concentration of 3×10¹⁸-6×10¹⁸ cm⁻³, and the dopant being Disilane (Si₂H₆);
An N-type AlGaInP current spreading layer, with a thickness of 1000-2500 nm, a composition of (AlₓGa₁₋ₓ)_{0.5}In_{0.5}P, where 0.6≤x≤1, a carrier concentration of 1×10¹⁸-3×10¹⁸ cm⁻³, and the dopant being Disilane (Si₂H₆);
An N-type electron blocking layer, having a multilayer superlattice structure composed of Al_{y}Ga_{1-y}InP (0.6≤y≤0.8), Al_{0.5}In_{0.5}P, and Al_{0.65}In_{0.35}P sublayers. The thickness of each sublayer gradually increases along the epitaxial growth direction, specifically determined by the following formula:

the thickness of layer n=initial thickness+(maximum thickness/total number of layers)×(n−1)

Where:
The maximum thickness of Al_{y}Ga_{1-y}InP sublayer is 10-20 nm, with an initial thickness of 3-5 nm;
The maximum thickness of Al_{0.5}In_{0.5}P sublayer is 15-25 nm, with an initial thickness of 5-7 nm;
The maximum thickness of Al_{0.65}In_{0.35}P sublayer is 5-10 nm, with an initial thickness of 1-3 nm;
The total number of layers is 10-25 pairs, with a Si doping concentration of 1×10¹⁸-2×10¹⁸ atoms/cm³, and the dopant being Disilane (Si₂H₆);
An N-type AlInP confinement layer, with a thickness of 150-350 nm, a carrier concentration of 7×10¹⁷-2×10¹⁸ cm⁻³, and the dopant being Disilane (Si₂H₆).

A multiple quantum well (MQW) layer, comprising 30-80 pairs of quantum wells and quantum barriers, where each pair consists of one quantum well and one quantum barrier, specifically:
Each quantum well has a thickness of 3-5 nm;
The thickness of the quantum barrier decreases progressively along the growth direction from 10-15 nm to 4-6 nm;
The Al content in the quantum barriers gradually increases from AlₐGa₁₋ₐInP (0.6≤a≤0.7) to Al_{b}Ga_{1-b}InP (0.8≤b≤0.9).

A P-type AlInP confinement layer, with a thickness of 250-600 nm, in which a magnesium diffusion blocking layer is set along its thickness direction. The magnesium diffusion blocking layer has:
A thickness of 50-150 nm;
A doping concentration of 1×10¹⁷-3×10¹⁷ atoms/cm³.

The remaining portion of the P-type AlInP confinement layer has a carrier concentration of 8×10¹⁷-1.5×10¹⁸ cm⁻³, and the dopant is bis(cyclopentadienyl)magnesium (Cp₂Mg).

A P-type GaP current spreading layer, which is divided into:
A bottom low magnesium-doped layer, with a thickness of 200-300 nm, a magnesium doping concentration of 3×10¹⁷-5×10¹⁷ atoms/cm³;
A top high magnesium-doped layer, with a thickness of 300-1500 nm, a magnesium doping concentration of 4×10¹⁸-8×10¹⁸ atoms/cm³, and the dopant is bis(cyclopentadienyl)magnesium (Cp₂Mg).

A P-type GaP ohmic contact layer, with a thickness of 30-100 nm, a carrier concentration of 5×10¹⁹-2×10²⁰ cm⁻³, and the dopant is carbon tetrabromide (CBr₄) or carbon tetrachloride (CCl₄).

Preferably, the thickness of the N-type AlGaInP current spreading layer is 1500-2000 nm, and the range of x is 0.7-0.9.

Preferably, the total number of layers in the N-type electron blocking layer is 15-20 pairs, and the thickness of each sublayer is designed according to the formula:

the thickness of layer n=initial thickness+(maximum thickness/total number of layers)×(n−1)

Preferably, the dopant in the N-type electron blocking layer is Disilane (Si₂H₆), and the doping concentration is 1.5×10¹⁸-2×10¹⁸ atoms/cm³.

Preferably, the number of quantum wells and quantum barriers in the multiple quantum well (MQW) layer is 40-60 pairs. The thickness of the quantum wells in the MQW layer is 4-5 nm, and the thickness of the quantum barriers decreases progressively from 10 nm to 5 nm. In the direction pointing towards the P-type AlInP confinement layer, the aluminum (Al) content in the quantum barriers gradually increases from AlₐGa₁₋ₐInP (0.65≤a≤0.7) to Al_{b}Ga_{1-b}InP (0.85≤b≤0.9).

Preferably, the thickness of the magnesium diffusion blocking layer in the P-type AlInP confinement layer is 80-120 nm, and the doping concentration is 1.5×10¹⁷-2.5×10¹⁷ atoms/cm³. If the magnesium diffusion blocking layer is too thick or the doping concentration is too low, it will affect hole injection efficiency. Conversely, if the thickness is too thin or the doping concentration is too high, it will not effectively block magnesium diffusion.

Preferably, the magnesium diffusion blocking layer is positioned at one-third of the P-type AlInP confinement layer's thickness, starting from the side closer to the multiple quantum well layer. Combined with the adjustment of the thickness and doping concentration of the magnesium diffusion blocking layer, if it is too far from the quantum well and close to the P-type GaP current spreading layer, excessive magnesium diffusion will occur, rendering the blocking layer ineffective and causing reliability issues. Conversely, if it is too close to the quantum well layer, hole injection efficiency will be insufficient, affecting the quantum injection efficiency.

Preferably, the low-doped layer of the P-type GaP current spreading layer has a thickness of 250-300 nm, and the magnesium doping concentration is 4×10¹⁷-5×10¹⁷ atoms/cm³.

Preferably, the high-doped layer of the P-type GaP current spreading layer has a thickness of 500-1000 nm, and the magnesium doping concentration is 5×10¹⁸-7×10¹⁸ atoms/cm³.

Preferably, the thickness of the P-type GaP ohmic contact layer is 50-80 nm, and the dopant is carbon tetrabromide (CBr₄).

Through the above technical solutions, the present invention achieves the following beneficial effects:

Enhancing electron migration efficiency and limiting electron leakage: By introducing an N-type electron blocking layer, the superlattice structure and the gradient variation of Al content significantly reduce electron mobility, minimizing electron leakage into the P-region, and improving the electron-hole recombination efficiency. Through a gradual thickness design, the electron blocking layer further optimizes the electron transport path with increasing thickness, effectively reducing non-radiative recombination.

Optimizing the luminous efficiency of the multiple quantum well (MQW) layer: The thickness of the quantum barrier layer gradually decreases from 10-15 nm to 4-6 nm, effectively improving hole injection efficiency. Simultaneously, with the gradient increase in the Al content of the quantum barrier layer, the bandgap width gradually increases, optimizing the synchronization efficiency of electrons and holes reaching the luminescent layer, thereby increasing the probability of radiative recombination. This design aims to adjust the position of the main luminescent layer to the center of the quantum well layer, improving luminous efficiency.

Suppressing magnesium diffusion and improving device stability: A low-doped magnesium diffusion blocking layer is set in the P-type AlInP layer, effectively reducing magnesium diffusion into the luminescent layer through a blocking effect, thereby minimizing non-radiative recombination caused by magnesium impurity energy levels. The thickness and doping concentration of the blocking layer are precisely designed to balance the suppression of magnesium diffusion and maintain hole injection efficiency.

Improving the performance of the P-type GaP current spreading layer: The P-type GaP current spreading layer is designed in two parts: the lower low-doped layer reduces the likelihood of magnesium diffusion into the luminescent layer, while the upper high-doped layer enhances current spreading capability and hole injection efficiency, further improving the luminous performance of the device.

Significantly improving device brightness and reliability: Multiple innovative designs work synergistically, significantly enhancing the electron-hole recombination probability, reducing carrier leakage and non-radiative recombination, and substantially improving the brightness and reliability of short-wavelength AlGaInP LEDs, particularly showing more stable performance under high-temperature conditions.

In conclusion, the present invention addresses the issues of brightness attenuation and insufficient device reliability in the prior art, making the AlGaInP yellow-green LED chip of the present invention significantly advantageous in terms of luminous efficiency and stability.

### BRIEF DESCRIPTION OF DRAWINGS

FIG. 1 is a structural schematic diagram of the high-brightness, low-leakage, and highly reliable AlGaInP yellow-green LED epitaxial wafer.

FIG. 2 illustrates the linear increase relationship of the thickness of each sublayer in the N-type electron blocking layer in Example 1.

FIG. 3 illustrates the structure of the P-type AlInP confinement layer.

FIG. 4 illustrates the structure of the P-type GaP current spreading layer.

FIG. 5 illustrates the forward voltage-current relationship of the yellow-green LED from Example 1 of the present invention, compared to a conventional yellow-green LED.

FIG. 6 illustrates the forward voltage-current relationship of the yellow-green LED from Example 2 of the present invention, compared to a conventional yellow-green LED.

FIG. 7 illustrates the forward voltage-current relationship of the yellow-green LED from Example 3 of the present invention, compared to a conventional yellow-green LED.

FIG. 8 illustrates the wavelength-current characteristics of the yellow-green LED from Example 1 of the present invention, compared to a conventional yellow-green LED.

FIG. 9 illustrates the wavelength-current characteristics of the yellow-green LED from Example 2 of the present invention, compared to a conventional yellow-green LED.

FIG. 10 illustrates the wavelength-current characteristics of the yellow-green LED from Example 3 of the present invention, compared to a conventional yellow-green LED.

FIG. 11 illustrates the relationship between luminous intensity and forward current of the yellow-green LED from Example 1 of the present invention, compared to a conventional yellow-green LED.

FIG. 12 illustrates the relationship between luminous intensity and forward current of the yellow-green LED from Example 2 of the present invention, compared to a conventional yellow-green LED.

FIG. 13 illustrates the relationship between luminous intensity and forward current of the yellow-green LED from Example 3 of the present invention, compared to a conventional yellow-green LED.

FIG. 14 illustrates the change in ΔLOP over time during normal-temperature aging for the yellow-green LED from the examples of the present invention, compared to a conventional yellow-green LED.

FIG. 15 illustrates the change in ΔLOP overtime during high-temperature aging for the yellow-green LED from the examples of the present invention, compared to a conventional yellow-green LED.

### DETAILED DESCRIPTION OF EMBODIMENTS

Below, preferred embodiments of the present invention are provided in conjunction with the accompanying drawings to describe the technical solutions of the invention in detail.

### Example 1

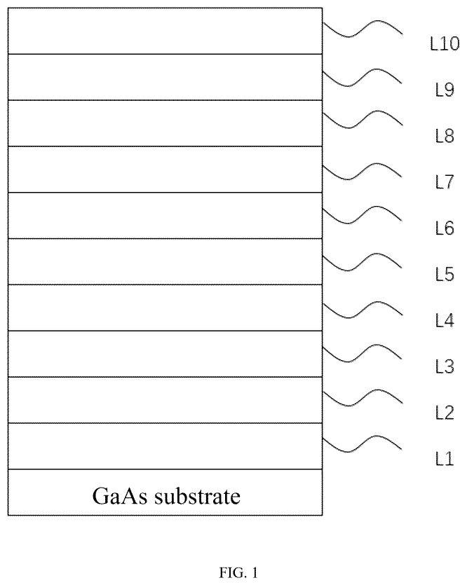

As shown in FIG. 1, this embodiment provides a high-brightness, low-leakage, and highly reliable AlGaInP yellow-green LED epitaxial wafer, comprising the following layers sequentially grown on a gallium arsenide (GaAs) substrate:
N-type GaAs buffer layer (L1): Thickness of 200 nm, doping concentration of 1.5×10¹⁸ atoms/cm³, dopant is Disilane (Si₂H₆).
N-type GaInP etch stop layer (L2): Thickness of 150 nm, doping concentration of 2×10¹⁸ atoms/cm³, dopant is Disilane (Si₂H₆).
N-type GaAs ohmic contact layer (L3): Thickness of 50 nm, carrier concentration of 4×10¹⁸ cm⁻³, dopant is Disilane (Si₂H₆).
N-type AlGaInP current spreading layer (L4): Thickness of 2000 nm, composition is (AlₓGa₁₋ₓ)_{0.5}In_{0.5}P, where x=0.7, carrier concentration of 2×10¹⁸ cm⁻³.

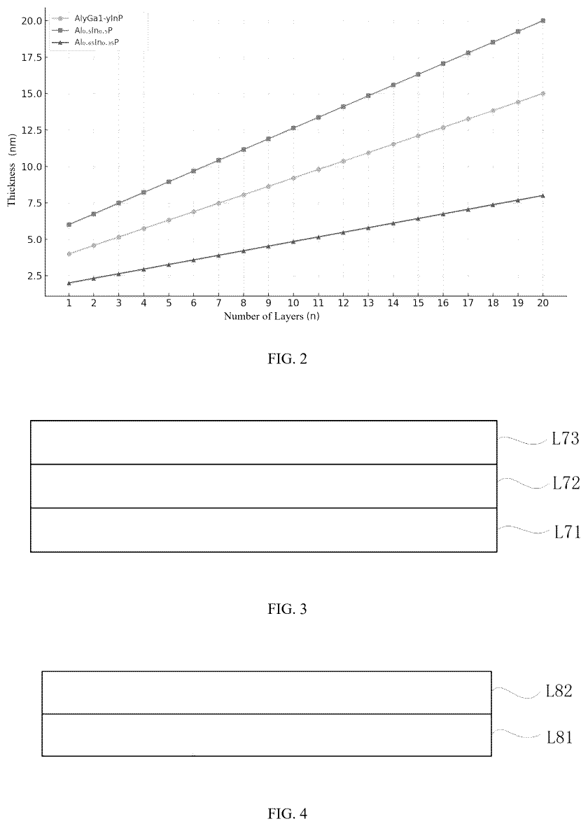

N-type electron blocking layer (L5): A multilayer superlattice structure, with a total of 20 pairs of sublayers. The thickness of each sublayer gradually increases along the growth direction, as shown in FIG. 2:

The maximum thickness of Al_{y}Ga_{1-y}InP sublayer is 15 nm, with an initial thickness of 4 nm.

The maximum thickness of Al_{0.5}In_{0.5}P sublayer is 20 nm, with an initial thickness of 6 nm.

The maximum thickness of Al_{0.65}In_{0.35}P sublayer is 8 nm, with an initial thickness of 2 nm.

N-type AlInP confinement layer (L6): Thickness of 300 nm, doping concentration of 1×10¹⁸ atoms/cm³.

The electron blocking layer utilizes the mobility variation of AlGaInP with changes in Al content. As the Al content increases, the electron mobility decreases. In particular, the last sublayer among the three groups has a high Al content, resulting in a wider bandgap, which imposes a stronger restriction on electron migration, effectively reducing electron mobility.

Multiple Quantum Well (MQW) Layer (L7): Contains 60 pairs of quantum wells and quantum barriers, with the following specific parameters:

Quantum well thickness: 4 nm.

Quantum barrier thickness: Gradually decreases linearly from 12 nm to 5 nm, improving hole injection efficiency.

The Al content increases gradually from AlₐGa₁₋ₐInP (a=0.65) to Al_{b}Ga_{1-b}InP (b=0.85).

As the Al content increases, the bandgap width of the quantum barrier layer gradually increases, which slows down the electron migration speed. This design effectively shifts the main luminescent layer to the center of the quantum well layer, improving the synchronization of electrons and holes reaching the luminescent layer and increasing the probability of radiative recombination.

P-type AlInP confinement layer (L8): Thickness of 500 nm, as shown in FIG. 3, including:

Lower P-type AlInP blocking layer (L71).

A magnesium diffusion blocking layer (L72) is set at one-third of the thickness direction, with a thickness of 50 nm and a doping concentration of 1×10¹⁷ atoms/cm³.

Upper P-type AlInP confinement layer (L73).

The magnesium diffusion blocking layer effectively reduces magnesium diffusion into the luminescent layer through its blocking effect, minimizing non-radiative recombination caused by impurity energy levels. The precise thickness and doping concentration design ensure effective magnesium diffusion suppression while maintaining sufficient hole injection efficiency.

P-type GaP current spreading layer (L9): As shown in FIG. 4, it is divided into two parts:

Bottom low-magnesium-doped layer (L91): Thickness of 200 nm, magnesium doping concentration of 4×10¹⁷ atoms/cm³.

Top high-magnesium-doped layer (L92): Thickness of 1000 nm, magnesium doping concentration of 6×10¹⁸ atoms/cm³.

The low-magnesium-doped layer reduces the likelihood of magnesium diffusion into the luminescent layer, while the high-magnesium-doped layer enhances the current spreading capability and hole injection efficiency, improving the luminous performance of the device.

P-type GaP ohmic contact layer (L10): Thickness of 50 nm, carrier concentration of 1×10²⁰ cm⁻³, dopant is carbon tetrabromide (CBr₄).

### Example 2

On the basis of Example 1, the following parameters are adjusted:

N-type electron blocking layer: The total number of layers is adjusted from 20 pairs to 15 pairs.

Multiple Quantum Well (MQW) layer: The number of quantum well-barrier pairs is reduced from 60 pairs to 50 pairs.

P-type AlInP confinement layer: The thickness of the magnesium diffusion blocking layer is adjusted to 100 nm, and the doping concentration is adjusted to 2×10¹⁷ atoms/cm³.

P-type GaP current spreading layer: The thickness of the low-magnesium-doped layer is adjusted to 300 nm.

### Example 3

On the basis of Example 2, the parameters are further optimized:

N-type electron blocking layer: An 18-pair superlattice structure is adopted.

Multiple Quantum Well (MQW) layer: The Al content in the quantum barriers gradually increases from AlₐGa₁₋ₐInP (a=0.7) to Al_{b}Ga_{1-b}InP (b=0.9). The thickness of the quantum barriers linearly decreases to 4 nm.

P-type GaP current spreading layer: The thickness of the low-magnesium-doped layer is adjusted to 250 nm.

### Testing Experiments

1. Device Preparation and Testing:

The epitaxial wafers of conventional structures and those from Examples 1, 2, and 3 were prepared using the Metal-Organic Chemical Vapor Deposition (MOCVD) method.

The electroluminescence (EL) spectroscopy method was used to measure the light output power and spectral distribution of the devices.

The I-V curves were used to measure the carrier leakage characteristics of the devices and to evaluate the leakage current levels.

High-temperature aging tests were conducted to evaluate the reliability and brightness attenuation of the devices under high-temperature conditions.

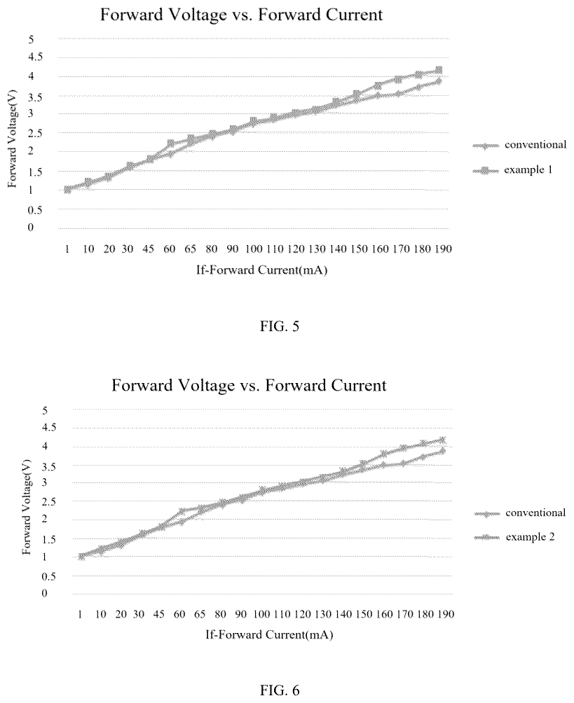

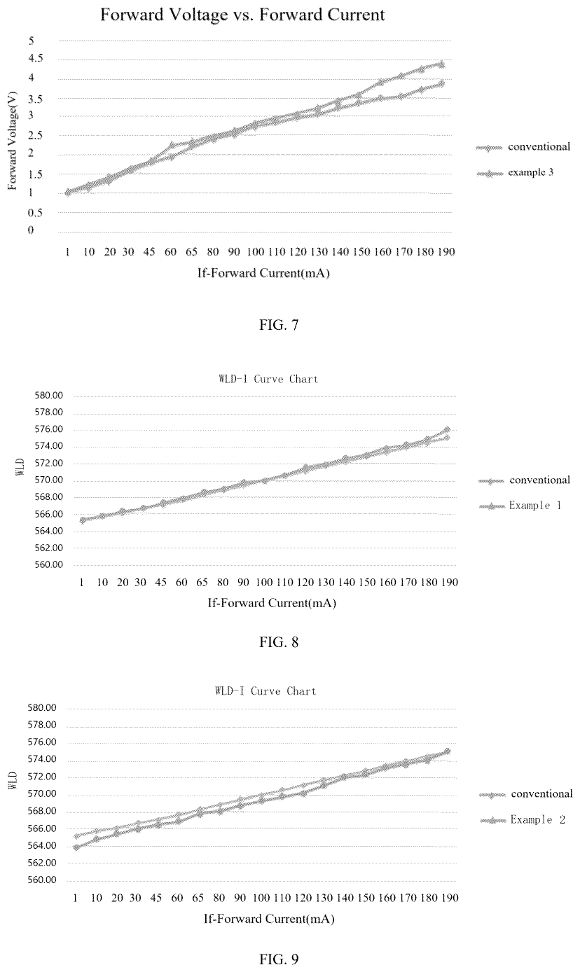

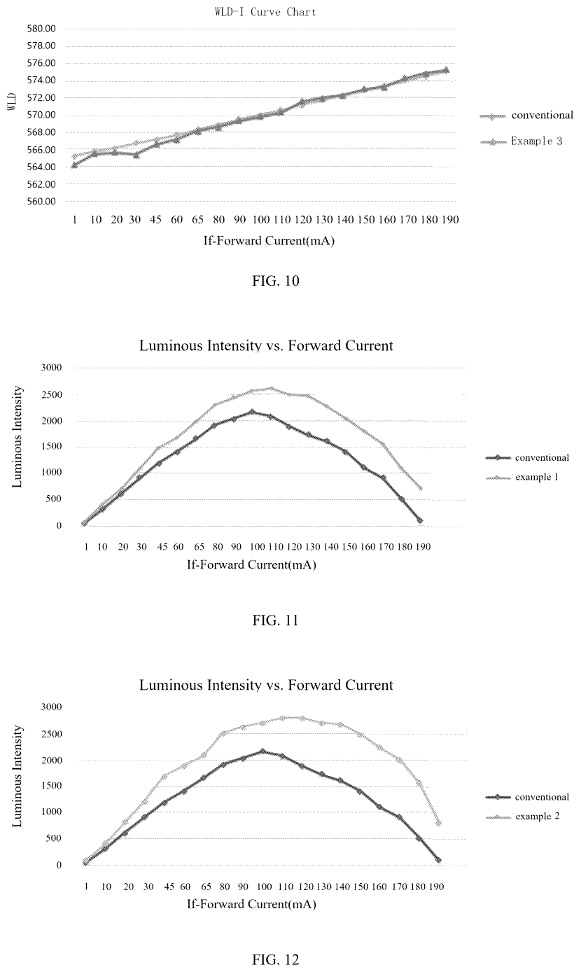

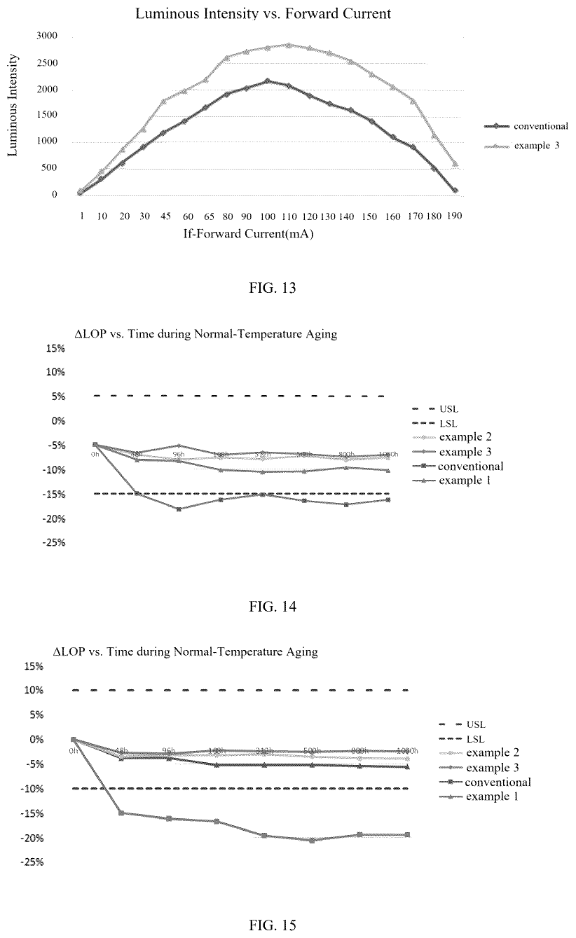

2. Experimental Results: Experimental Results: As shown in FIGS. 5-15 and Table 1. Table 1 presents the data measured at a test current of 60 mA.

TABLE 1
Chip size: 14 mil × 14 mil

| Sample | VF (V) | WLD (nm) | LOP (mcd) |
|---|---|---|---|
| Example 1 | 2.24 | 568.7 | 1980 |
| Example 2 | 2.24 | 567.9 | 2031 |
| Example 3 | 2.26 | 568.2 | 2067 |
| Conventional | 2.21 | 568.5 | 1720 |

### Parameter Description:

VF (V): Forward Voltage, measured in volts (V).

WLD (nm): Wavelength Dominant, measured in nanometers (nm).

LOP (mcd): Luminous Output Power, measured in millicandela (mcd).

### Observations:

### Brightness Improvement Effect:

In Example 1, the luminous output power of the device increased by approximately 15% compared to the conventional structure and maintained stable output at 60° C.

In Examples 2 and 3, further optimization of the Al content and magnesium diffusion suppression effect resulted in brightness improvements of 18% and 20%, respectively, compared to the conventional structure.

### Carrier Leakage Suppression:

Experimental results show that the N-type electron blocking layer effectively suppresses electron leakage. Under the same number of quantum well pairs, the saturation current of Example 1 was improved by 10 mA compared to the conventional structure.

### High-Temperature Stability:

After 1,000 hours of continuous aging at 85° C. with a current of 75 mA, the brightness attenuation of Example 1 was only 4%, whereas the conventional device exhibited an attenuation of 17%.

In Examples 2 and 3, the brightness attenuation was further reduced to 3% and 2.5%, respectively, demonstrating higher reliability.

3. Experimental Conclusions:

Through verification by the above examples and experimental data, the AlGaInP yellow-green LED epitaxial wafer provided by the present invention has the following advantages:

Significantly improved device brightness and luminous efficiency.

Effectively suppressed carrier leakage and non-radiative recombination, reducing leakage current.

Enhanced operational stability and reliability under high-temperature conditions.

Further delayed device brightness attenuation through precise design of the magnesium diffusion blocking layer.

What is claimed is:

1. A high-brightness, low-leakage, and highly reliable AlGaInP yellow-green light-emitting diode (LED) epitaxial wafer, characterized by comprising the following layers sequentially grown on a gallium arsenide (GaAs) substrate:
N-type GaAs buffer layer: Thickness of 150-200 nm, Si doping concentration of 1×10¹⁸-2×10¹⁸ atoms/cm³, dopant is Disilane (Si₂H₆);
N-type GaInP etch stop layer: Thickness of 100-200 nm, Si doping concentration of 1×10¹⁸-3×10¹⁸ atoms/cm³, dopant is Disilane (Si₂H₆);
N-type GaAs ohmic contact layer: Thickness of 30-100 nm, carrier concentration of 3×10¹⁸-6×10¹⁸ cm⁻³, dopant is Disilane (Si₂H₆);
N-type AlGaInP current spreading layer: Thickness of 1000-2500 nm, composition (AlₓGa₁₋ₓ)_{0.5}In_{0.5}P, where 0.6≤x≤1, carrier concentration of 1×10¹⁸-3×10¹⁸ cm⁻³, dopant is Disilane (Si₂H₆);
N-type electron blocking layer: With a multilayer superlattice structure composed of Al_{y}Ga_{1-y}InP (0.6≤y≤0.8), Al_{0.5}In_{0.5}P, and Al_{0.65}In_{0.35}P sublayers, where the thickness of each sublayer increases progressively along the epitaxial growth direction, determined by the formula:
$$the thickness of layer n = initial thickness + ( maximum thickness / total number of layers ) \times ( n - 1 ) ,$$
where:
Maximum thickness of Al_{y}Ga_{1-y}InP sublayer: 10-20 nm, initial thickness: 3-5 nm;
Maximum thickness of Al_{0.5}In_{0.5}P sublayer: 15-25 nm, initial thickness: 5-7 nm;
Maximum thickness of Al_{0.65}In_{0.35}P sublayer: 5-10 nm, initial thickness: 1-3 nm;
Total number of layers: 10-25 pairs, Si doping concentration: 1×10¹⁸-2×10¹⁸ atoms/cm³, dopant is Disilane (Si₂H₆);
N-type AlInP confinement layer: Thickness of 150-350 nm, carrier concentration of 7×10¹⁷-2×10¹⁸ cm⁻³, dopant is Disilane (Si₂H₆);
Multiple Quantum Well (MQW) layer: Consisting of 30-80 pairs of quantum wells and quantum barriers, where:
Each quantum well thickness: 3-5 nm;
Quantum barrier thickness decreases progressively from 10-15 nm to 4-6 nm along the growth direction;
The Al content in the quantum barriers gradually increases from AlₐGa₁₋ₐInP (0.6≤a≤0.7) to Al_{b}Ga_{1-b}InP (0.8≤b≤0.9);
P-type AlInP confinement layer: Thickness of 250-600 nm, with a magnesium diffusion blocking layer set within the thickness direction. The magnesium diffusion blocking layer has:
Thickness: 50-150 nm;
Doping concentration: 1×10¹⁷-3×10¹⁷ atoms/cm³;
The remaining part of the confinement layer has a carrier concentration of 8×10¹⁷-1.5×10¹⁸ cm⁻³, dopant is bis(cyclopentadienyl)magnesium (Cp₂Mg);
P-type GaP current spreading layer: Divided into:
Bottom low magnesium-doped layer: Thickness of 200-300 nm, Mg doping concentration of 3×10¹⁷-5×10¹⁷ atoms/cm³;
Top high magnesium-doped layer: Thickness of 300-1500 nm, Mg doping concentration of 4×10¹⁸-8×10¹⁸ atoms/cm³, dopant is bis(cyclopentadienyl)magnesium (Cp₂Mg); P-type GaP ohmic contact layer: Thickness of 30-100 nm, carrier concentration of 5×10¹⁹-2×10²⁰ cm³, dopant is carbon tetrabromide (CBr₄) or carbon tetrachloride (CCl₄).

2. The AlGaInP yellow-green LED epitaxial wafer according to claim 1, characterized in that the total number of layers in the N-type electron blocking layer is 15-20 pairs, and the thickness of each sublayer is designed according to the formula:
$$the thickness of layer n = initial thickness + ( maximum thickness / total number of layers ) \times ( n - 1 ) .$$

3. The AlGaInP yellow-green LED epitaxial wafer according to claim 1, characterized in that the dopant in the N-type electron blocking layer is Disilane (Si₂H₆), with a doping concentration of 1.5×10¹⁸-2×10¹⁸ atoms/cm³.

4. The AlGaInP yellow-green LED epitaxial wafer according to claim 1, characterized in that the multiple quantum well layer consists of 40-60 pairs of quantum wells and quantum barriers, where:
Quantum well thickness: 4-5 nm;
Quantum barrier thickness decreases progressively from 10 nm to 5 nm;
The Al content in the quantum barriers increases gradually from AlₐGa₁₋ₐInP (0.65≤a≤0.7) to Al_{b}Ga_{1-b}InP (0.85≤b≤0.9).

5. The AlGaInP yellow-green LED epitaxial wafer according to claim 1, characterized in that the thickness of the magnesium diffusion blocking layer in the P-type AlInP confinement layer is 80-120 nm, with a doping concentration of 1.5×10¹⁷-2.5×10¹⁷ atoms/cm³.

6. The AlGaInP yellow-green LED epitaxial wafer according to claim 1, characterized in that the magnesium diffusion blocking layer is positioned at one-third of the thickness of the P-type AlInP confinement layer, starting from the side closer to the multiple quantum well layer.

7. The AlGaInP yellow-green LED epitaxial wafer according to claim 1, characterized in that the low-doped layer of the P-type GaP current spreading layer has a thickness of 250-300 nm, and a magnesium doping concentration of 4×10¹⁷-5×10¹⁷ atoms/cm³.

8. The AlGaInP yellow-green LED epitaxial wafer according to claim 1, characterized in that the high-doped layer of the P-type GaP current spreading layer has a thickness of 500-1000 nm, and a magnesium doping concentration of 5×10¹⁸-7×10¹⁸ atoms/cm³.

9. The AlGaInP yellow-green LED epitaxial wafer according to claim 1, characterized in that the P-type GaP ohmic contact layer has a thickness of 50-80 nm, and the dopant is carbon tetrabromide (CBr₄).

10. The AlGaInP yellow-green LED epitaxial wafer according to claim 1, characterized in that the N-type AlGaInP current spreading layer has a thickness of 1500-2000 nm, and the range of x is 0.7-0.9.
